(19) United States
(12) Patent Application Publication
(10) Pub. No.: US 2009/0197034 A1
(43) Pub. Date: Aug. 6, 2009

(54) METHOD OF MANUFACTURING A STAMPER FOR REPLICATING A HIGH DENSITY RELIEF STRUCTURE

(76) Inventors: Erwin R. Meinders, Eindhoven (NL); Julien J.X. De Loynes De Fumichon, Eindhoven (NL)

Correspondence Address: Muncy, Geissler, Olds & Lowe, PLLC, P.O. BOX 1364, FAIRFAX, VA, 22038-1364, US

(21) Appl. No.: 12/065,498

(22) PCT Filed: Aug. 25, 2006
(86) PCT No.: PCT/IB06/52954

§ 371 Date: Sep. 2, 2008

(30) Foreign Application Priority Data
Sep. 2, 2005 (EP) 05108062.0

(51) Int. Cl. B32B 3/30; G03F 7/20

(52) U.S. Cl. 428/64.4; 430/320; 428/172

(57) ABSTRACT

The present invention relates to a method of manufacturing a stamper for replicating a high density relief structure, the method comprising the steps of: providing a master substrate (10) comprising a substrate layer (12) and a recording stack overlying the substrate layer, the recording stack comprising a mask layer (14) and an interface layer (16) between the mask layer and the substrate layer, and the mask layer comprising a phase transition material, projecting a laser beam onto selected regions (20) of the mask layer, thereby inducing a heat-related phase transition for changing the properties of the selected regions of the mask layer with respect to chemical agents, applying a chemical agent to the mask layer for removing the selected regions of the mask layer, thereby uncovering regions (22) of the interface layer, and plasma etching the recording stack, thereby forming pits (24) in the uncovered regions of the interface layer. The present invention further relates to a stamper and an optical disc.

### FIELD OF THE INVENTION

The present relation relates to a method of manufacturing a stamper for replicating a high density relief structure, and particularly to the manufacturing of a stamper by using phase transition materials.

### BACKGROUND OF THE INVENTION

Phase-transition mastering (PTM) is a method to make high-density ROM and RE/R stampers for mass fabrication of optical discs. Phase-transition materials, also called phase-change materials, can be transformed from the initial unwritten state to a different state via laser-induced heating. Heating of the recording stack can, for example, cause mixing, melting, amorphisation, phase separation, decomposition, etc. One of the two phases, the initial or the written state, dissolves faster in acids or alkaline development liquids than the other phase does. In this way, a written data pattern can be transformed to a high-density relief structure with protruding bumps or pits. The patterned substrate can be used as stamper for the mass fabrication of high-density optical discs or as a stamp for micro-contact printing.

One of the challenges encountered with PTM is getting a good pit shape. Since the PTM method is based on heating, the temperature profile in the recording stack has a considerable influence on the shape of the pits. The problem lies in the fact that most materials have either a rather high absorption rate (most metals) or a rather low absorption rate (most dielectrics). Materials with a high absorption rate have a bad absorption profile. While the heat is penetrating the stack, the high absorption rate gives a rapid decrease in power flux and thus a rapid decrease in the temperatures that is reached. This makes it hard to get the needed pit depth. Materials with a low absorption rate would have a very good pit shape, but getting the needed temperatures would require very large write powers.

One of the possibilities to overcome these problems is the use of a mask stack. A highly absorbing and selectively etchable material is placed on an etchable dielectric material. Selectively etchable means that only the written or the unwritten state is etchable. Unselectively etchable means that both the written and the unwritten state are etchable. In this stack with the mask layer, the absorbing layer is very thin and the absorption profile is not an issue.

Therefore, a master substrate was already proposed that comprises a substrate layer and a recording stack deposited on the substrate layer. The recording stack comprises a mask layer and an interface layer sandwiched between the mask layer and the substrate. The mask layer comprises a phase-change material, and marks are written by crystallisation of the phase-change material. The crystalline marks have a faster dissolution rate than the initial amorphous state, such that a pit pattern remains. Due to this pit pattern, the interface layer is also exposed to the etching liquid such that the pit structure is transmitted to the interface layer. In this way, a much deeper pit structure remains with steep walls, i.e. a high contrast. One of the disadvantages of this etching method is the possibility of under etching of the interface layer. The total dissolution time is then very critical.

It is therefore an object of the invention to provide a method of manufacturing a stamper for replicating a high density relief structure that provides a deep pit structure without the disadvantage of under etching.

### SUMMARY OF THE INVENTION

The above objects are solved by the features of the independent claims. Further developments and preferred embodiments of the invention are outlined in the dependent claims.

In accordance with the invention, there is provided a method of manufacturing a stamper for replicating a high density relief structure, the method comprising the steps of:

providing a master substrate comprising a substrate layer and a recording stack overlying the substrate layer, the recording stack comprising a mask layer and an interface layer between the mask layer and the substrate layer, and the mask layer comprising a phase-transition material,

projecting a laser beam onto selected regions of the mask layer, thereby inducing a heat-related phase transition for changing the properties of the selected regions of the mask layer with respect to chemical agents,

applying a chemical agent to the mask layer for removing the selected regions of the mask layer, thereby uncovering regions of the interface layer, and

plasma etching the recording stack, thereby forming pits in the uncovered regions of the interface layer.

By the plasma-etching step, a deep pit structure can be provided, and the possible disadvantage of under etching can be ruled out. In contrast to an isotropic wet etching technique, a plasma etching is anisotropic, so that a deep pit structure with steep walls can be provided.

According to a preferred embodiment, the interface layer is provided directly adjacent the substrate layer. On this basis, the pit structure can be even deeper than the thickness of the interface layer, namely by proceeding the plasma etching into the substrate.

According to a different embodiment, a plasma-etch-resistant layer is provided between the interface layer and the substrate layer. By this plasma-etch-resistant layer, an etch stop is provided. Consequently, the etching time can be selected long enough, such that the problem of possible under etching is overcome.

For example, the plasma-etch-resistant layer comprises Ag.

Preferably, the plasma-etch-resistant layer has a thickness in the range from 10 nm to 300 nm, in particular between 40 and 200 nm.

The thicknesses and materials of the mask layer and the interface layer can preferably be chosen as follows.

For example, the mask layer has an initial thickness in the range from 2 nm to 50 nm, preferably between 5 and 40 nm.

Preferably, the phase transition material comprises a Sn—Ge—Sb-alloy material, in particular with the composition Sn_{18.3}—Ge_{12.6}—Sb_{69.2}.

Further, for example, the interface layer has an initial thickness in the range from 5 nm to 200 nm, in particular between 20 and 110 nm.

It is preferred that the interface layer comprises Si₃N₄. With a proper selection of the chemical agent for etching the mask layer, Si₃N₄ is essentially non-sensitive to the chemical agent.

For example, the chemical agent comprises HNO₃ in a concentration between 0.5 and 10%, in particular between 3 and 7%.

According to a further example, the chemical agent comprises KOH in a concentration between 1 and 20%, in particular between 5 and 15%.

With respect to the pit forming it is preferred that the plasma etching comprises the application of fluorine plasma.

It is possible that the mask layer is removed after plasma etching. Such a stripping of the mask layer is particularly useful, if the mask layer is deteriorated due to the application of the chemical agent but not fully sacrificed.

The present invention further relates to a stamper manufactured by a method according to the present invention and to an optical disc manufactured by employing such a stamper.

These and other aspects of the invention will be apparent from and elucidated with reference to the embodiments described hereinafter.

### BRIEF DESCRIPTION OF THE DRAWINGS

FIGS. 1 to 4 illustrate steps of a method according to the present invention by illustrating cross sectional views of a recording stack.

FIG. 5 shows atomic force microscope (AFM) data recorded on the basis of a recording stack after application of the chemical agent and before plasma etching.

FIG. 6 shows AFM data recorded on the basis of a recording stack after application of the chemical agent and after plasma etching.

FIG. 7 shows an AFM picture of data after developing the stack with NaOH.

FIG. 8 shows an AFM picture of data after developing the stack with KOH.

### DESCRIPTION OF PREFERRED EMBODIMENTS

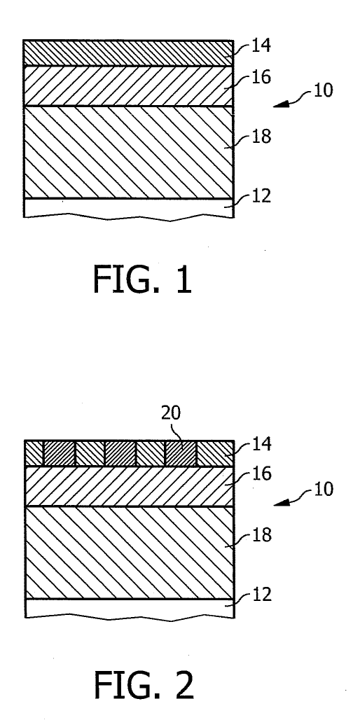

FIGS. 1 to 4 illustrate steps of a method according to the present invention by illustrating cross sectional views of a recording stack. In FIG. 1, a master substrate 10 is illustrated. The master substrate 10 is formed by a substrate layer 12, for example consisting of polycarbonate, that carries a layer stack comprising a mask layer 14 on top of the layer stack, an interface layer 16 below the mask layer 14 and a silver layer 18 between the interface layer 16 and the substrate layer 12. For example, the mask layer 14 is formed from a 20 nm thick SnGeSb alloy, the interface layer 16 is formed from Si₃Ni₄, 50 nm thick, and the silver layer has a thickness of 100 nm.

FIG. 2 shows the same stack after writing marks by a laser beam recorder. For example, a 405 nm laser beam recorder can be used to write marks onto selected regions 20 in the amorphous SnGeSb phase-transition layer 14. A recording speed of 2 m/s can be used. The result is a mask layer 14 that is partly amorphous, namely in the regions that have not been illuminated, and partly crystalline, namely in the selected region 20.

FIG. 3 shows the result of applying a chemical agent to the mask layer. For example, HNO₃ having a concentration between 0.5 and 10%, preferably 5%. Such an agent removes the crystalline marks much faster than the amorphous background material. Due to the proper selection of the interface layer 16 material and the chemical agent, only the mask layer is patterned.

FIG. 4 shows the result of a subsequent anisotropic plasma-etching step. The patterned SnGeSb layer on top of the interface layer 16 serves as a mask layer 14; only the uncovered regions 24 of the interface layer 16 are exposed to the plasma. Consequently, only these regions are anisotropically etched. The pit structure formed in the mask layer 14 by the laser beam recorder writing and wet etching is transformed to the interface layer 16. Plasma etching may proceed up to the bottom of the interface layer 16 and is stopped by the underlying silver layer 18 which is etch-resistant. A deeper pit structure can be obtained when the etching proceeds into the substrate 12 as well, i.e. in the absence of the etch-resistant layer 18.

In a further step, that is not illustrated in the drawings, it is possible to strip off the mask layer after the plasma etching step. This is particularly useful, if the mask layer is deteriorated but not fully sacrificed.

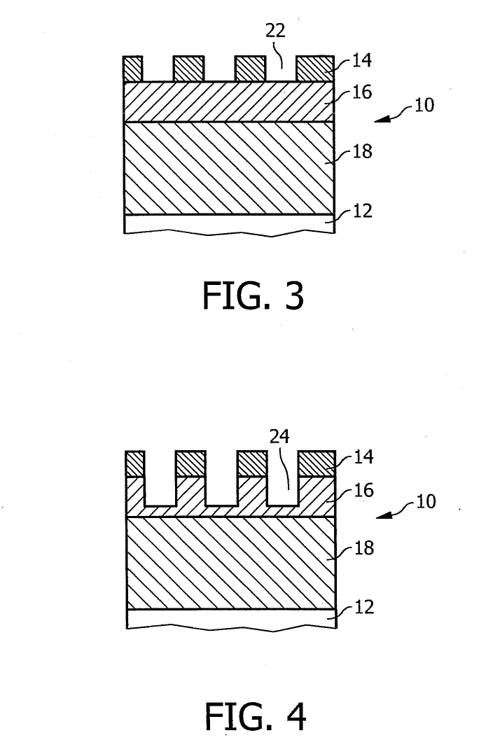

FIG. 5 shows atomic force microscope (AFM) data recorded on the basis of a recording stack after application of the chemical agent and before plasma etching. The illustrated AFM data have been collected on the basis of a data writing process using a 405 nm laser beam recorder at 2.3 mW laser power, a 20 nm SnGeSb mask layer, and one minute of development with 5% HNO₃. The resulting pit depth is 20 nm, which equals the initial mask layer thickness.

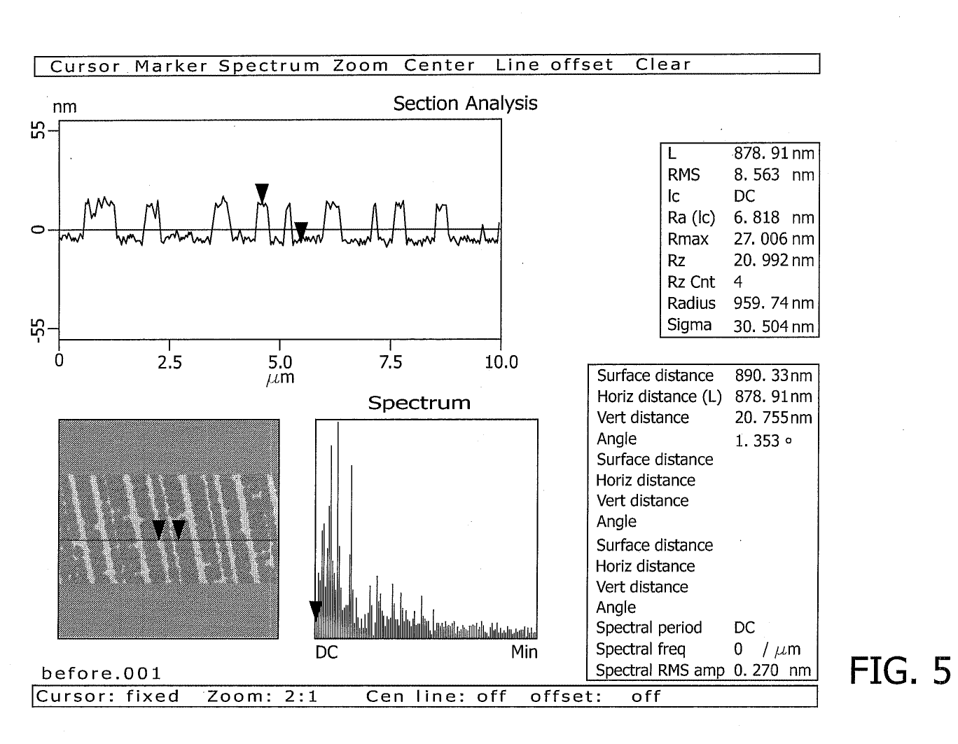

FIG. 6 shows AFM data recorded on the basis of a recording stack after application of the chemical agent and after plasma etching. After a 20 minutes plasma etching process with fluorine plasma, the mask layer appears to be substantially inert to the plasma, thus remaining substantially untouched. The underlying Si₃N₄ layer was unisotropically etched in the regions exposed to the fluorine plasma. The resulting pit depth is about 50 nm. The varying distance between the marks is related to a varying track pitch due to the data writing by the laser beam recorder.

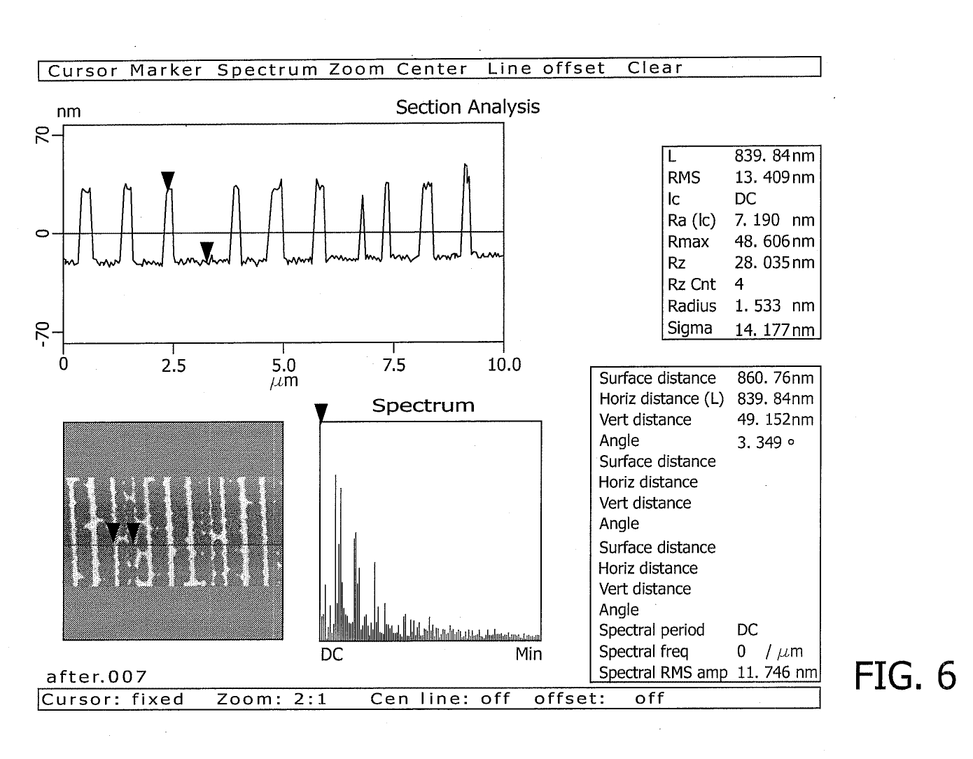

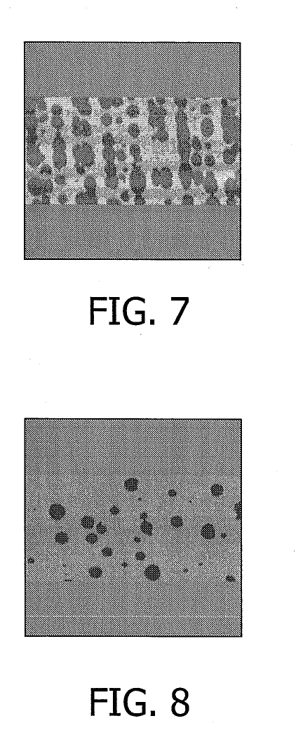

FIG. 7 shows an AFM picture of data after developing the stack with NaOH and FIG. 8 shows an AFM picture of data after developing the stack with KOH. Also these pictures have been collected by an atomic force microscope on the basis of data written with the 405 nm laser beam recorder in the 20 nm SnGeSb mask layer after two minutes of development with 5% NaOH (FIG. 7) and one minute of development with 10% KOH (FIG. 8).

Equivalents and modifications not described above may also be employed without departing from the scope of the invention, which is defined in the accompanying claims.

1. A method of manufacturing a stamper for replicating a high density relief structure, the method comprising the steps of:
providing a master substrate comprising a substrate layer and a recording stack overlying the substrate layer, the recording stack comprising a mask layer and an interface layer between the mask layer and the substrate layer, and the mask layer comprising a phase-transition material,
projecting a laser beam onto selected regions of the mask layer, thereby inducing a heat-related phase-transition for changing the properties of the selected regions of the mask layer with respect to chemical agents,
applying a chemical agent to the mask layer for removing the selected regions of the mask layer, thereby uncovering regions of the interface layer, and
plasma etching the recording stack, thereby forming pits in the uncovered regions of the interface layer.

2. The method according to claim 1, wherein the interface layer is provided directly adjacent the substrate layer.

3. The method according to claim 1, wherein a plasma-etch-resistant layer is provided between the interface layer and the substrate layer.

4. The method according to claim 3, wherein the plasma-etch-resistant layer comprises Ag.

5. The method according to claim 3, wherein the plasma-etch-resistant layer has a thickness in the range from 10 nm to 300 nm, in particular between 40 and 200 nm.

6. The method according to claim 1, wherein the mask layer has an initial thickness in the range from 2 nm to 50 nm, preferably between 5 and 40 nm.

7. The method according to claim 1, wherein the phase transition material comprises a Sn—Ge—Sb-alloy material, in particular with the composition Sn18.3-Ge12.6-Sb69.2.

8. The method according to claim 1, wherein the interface layer has an initial thickness in the range from 5 nm to 200 nm, in particular between 20 and 110 nm.

9. The method according to claim 1, wherein the interface layer comprises Si3N4.

10. The method according to claim 1, wherein the chemical agent comprises HNO3 in a concentration between 0.5 and 10%, in particular between 3 and 7%.

11. The method according to claim 1, wherein the chemical agent comprises KOH in a concentration between 1 and 20%, in particular between 5 and 15%.

12. The method according to claim 1, wherein the plasma etching comprises the application of fluorine plasma.

13. The method according to claim 1, wherein the mask layer is removed after plasma etching.

14. A stamper manufactured by a method according to claim 1.

15. An optical disc manufactured by employing a stamper according to claim 14.
